(19) United States
(12) Patent Application Publication
(10) Pub. No.: US 2017/0082466 A1
(43) Pub. Date: Mar. 23, 2017

(54) Electronic Module, Method and Device for Manufacturing an Electronic Module

(71) Applicant: Robert Bosch GmbH, Stuttgart (DE)

(72) Inventors: Dominik Geisler, Tuebingen (DE); Ricardo Ehrenpfordt, Korntal-Muenchingen (DE); Viktor Morosow, Reutlingen (DE); Frederik Ante, Stuttgart (DE)

(21) Appl. No.: 15/126,237

(22) PCT Filed: Feb. 19, 2015
(86) PCT No.: PCT/EP2015/053458

§ 371 Date: Sep. 14, 2016

(30) Foreign Application Priority Data
Mar. 14, 2014 (DE) 10 2014 204 722.6

(51) Int. Cl. G01D 11/24; H01L 23/04; H01L 23/13

(52) U.S. Cl. CPC G01D 11/245; H01L 23/13; H01L 23/04; H01L 2224/16225; H01L 2224/32145; H01L 2224/32245; H01L 2224/45144; H01L 2224/48247; H01L 2224/73265; H01L 24/17

(57) ABSTRACT

An electronic module includes at least one support plate and at least one electronic component. The at least one support plate defines at least one through opening and has a contact side that includes at least one contact element. The at least one electronic module includes at least one electronic component positioned on the contact side of the support plate opposite the through opening. The at least one contact element projects beyond the at least one electronic component.

### PRIOR ART

The present invention relates to an electronic module, to a method for producing an electronic module, to a corresponding apparatus, to a corresponding computer program product and also to a corresponding storage medium.

Sensor elements can be surrounded by a housing in order to provide protection against environmental influences. A housing of this kind can be produced, for example, using an injection-molding method.

### DISCLOSURE OF THE INVENTION

Against this background, an electronic module, a method for producing a module of this kind, furthermore an apparatus which uses said method, a corresponding computer program product and also finally a corresponding storage medium as claimed in the main claims are presented using the approach presented here. Advantageous refinements can be gathered from the respective dependent claims and the following description.

The invention presents an electronic module having the following features:
at least one support plate, wherein a contact-making side of the support plate has at least one contact element; and
at least one electronic component which is arranged on the contact-making side, wherein the contact element projects beyond the electronic component.

A support plate can be understood to mean a substrate for receiving an electronic component. By way of example, the support plate may be a plate comprising metal conductor tracks. A contact element can be understood to mean an element which is designed in order to electrically and/or mechanically connect the support plate, for example, to a further plate. The contact element can be realized, for example, as a solder ball.

The present approach is based on the knowledge that a support substrate of an electronic module can be used to cover an electronic component. The support substrate can further have a contact element which projects beyond the electronic component. As a result, electrical contact can be made with the electronic module and said electronic module can be fixed in one step. Since, for example, a sensor chip is protected by a functional support in this way, a cost-effective sensor housing with media access on one or both sides and the option of chip stacking can be provided.

On the basis of a packaging concept which is simplified in this way, different requirements in respect of a particle and light influence can be realized in a highly flexible manner, such as chips with covered sensitive regions or EMC protection (EMC electromagnetic compatibility) for example. By way of example, special MCT concepts (MCT=mounting and connection technique) in the form of stacking infrared sources and infrared detectors can be provided for gas sensors. Therefore, a design of an electronic module can be kept as compact as possible.

Since a support substrate and, for example, solder balls are used instead of a metal cover and a molding compound for covering purposes, the costs of the mounting and connection technique can be reduced.

The costs of a mounting and connection technique can be reduced on account of a molding step being dispensed with.

Furthermore, the present approach allows a covered sensitive structure to be realized by means of an undercut.

A sealing ring can optionally be used to provide protection against solder splashes and flux vapors.

A lateral space requirement can be reduced on account of wire bonds being dispensed with.

Since the support substrate in the form of a cover is itself a functional support or rewiring support, two semiconductor components which interact, for example, by radiation can be stacked in a simple manner.

The support plate can have at least one passage opening. In this case, the passage opening can be arranged opposite the electronic component and can be in the form of a fluidic channel between the contact-making side and a side of the support plate which is situated opposite the contact-making side. Media access to the electronic component can be realized via the passage opening using simple and cost-effective means.

The electronic module can be provided with at least one connecting element which electrically conductively connects the electronic component to the support plate. In this case, the connecting element can be arranged between the electronic component and the support plate in order to form, at least in the region of the passage opening, an intermediate space between the electronic component and the support plate. As an alternative or in addition, the support plate can be at least partially produced from a plastic. A connecting element can be understood to mean a spacer. The connecting element can be realized as an electrical connection contact, for example in the form of a solder ball. The support plate may be a printed circuit board which is composed of plastic. By way of example, the printed circuit board can be produced from a thermoset, in particular a thermoset with incorporated glass fibers. The support plate can be provided in a particularly cost-effective manner in this way. Various physical properties of an external environment of the electronic module can be detected by means of the intermediate space. By way of example, the electronic component can have a sensitive region for this purpose.

According to a further embodiment of the present approach, the electronic module can have a sealing edge which is formed at least partially around the passage opening between the electronic component and the support plate in order to connect the electronic component to the support plate in an at least partially fluid-tight manner. The intermediate space between the electronic component and the support plate can be laterally delimited and sealed off by means of the sealing edge.

Furthermore, the electronic component can have a sensitive region for detecting at least one physical property of the external environment of the electronic module. In this case, the sensitive region can be arranged opposite the contact-making side. A sensitive region can be understood to mean a region of a sensor element which is designed to detect certain physical properties such as pressure, temperature, moisture, specific gases or brightness of the external environment for example. The sensitive region can be fluidically connected to the external environment via the passage opening. Therefore, a sensor function of the electronic module can be realized with low levels of expenditure in respect of costs and production. As an alternative or in addition, the sensitive region can be arranged opposite the passage opening. As a result, a distance between the external environment of the electronic module and the sensitive region can be kept as low as possible and a high degree of accuracy when detecting the physical properties of the external environment can be ensured. By way of example, it is therefore possible for light passing through the passage opening to directly strike the sensitive region.

According to a further embodiment of the present approach, the contact-making side can have an active structure for influencing at least one physical property of an external environment of the sensitive region. In this case, the active structure can be arranged opposite the sensitive region. An active structure can be understood to mean, for example, a radiation source which is directed onto the sensitive region, for example in the form of a heating structure or an infrared source, or a diaphragm. The active structure may also be a further sensitive structure, that is to say a further sensor. Efficiency of the sensor function of the electronic module can be improved by means of the active structure.

The electronic module can be provided with at least one further electronic component which, on a side of the support plate which is situated opposite the contact-making side, is arranged opposite the passage opening and is electrically conductively connected to the support plate. Therefore, a plurality of electronic components can be combined with one another in a space-saving manner.

In this case, the further electronic component can have an active region for influencing at least one physical property of an external environment of the further electronic component. The active region can be arranged opposite the passage opening in particular. Therefore, the active region can interact with the sensitive region of the electronic component via the passage opening. The active region may be, for example, a radiation source or a diaphragm. The active region may also be a further sensitive structure, that is to say a further sensor. A functional scope of the electronic module can be extended in a flexible, space-saving and cost-efficient manner on account of this embodiment.

The electronic module can further comprise a cover element which is fastened to that side of the support plate which is situated opposite the contact-making side and at least partially projects beyond the further electronic component in order to protect said further electronic component against environmental influences. A cover element of this kind provides the advantage of particularly cost-effective production.

Furthermore, the contact-making side can have at least one further contact element, wherein the further contact element projects beyond the electronic component. In this case, the further contact element can be arranged adjacent to a first edge of the electronic component and/or the contact element can be arranged adjacent to a second edge of the electronic component, which second edge is situated opposite the first edge. The electronic module can be securely fixed and contact can be made with said electronic module in a flexible manner in this way.

A particularly compact design of the electronic module can be realized when, according to a further embodiment of the present approach, an axis of main extent of the support plate and an axis of main extent of the electronic component point in different directions. An axis of main extent can be understood to mean an axis of a greatest extent of the support plate and, respectively, of the electronic component. By way of example, a longitudinal axis of the support plate can be arranged transverse to a longitudinal axis of the electronic component.

The present approach additionally provides a method for producing an electronic module according to one of the embodiments described in this document, wherein the method comprises the following steps:
providing at least one support plate, wherein a contact-making side of the support plate has at least one contact element, and also at least one electronic component; and
forming a composite from the support plate and the electronic component, wherein the electronic component is arranged on the contact-making side, wherein the contact element projects beyond the electronic component.

The approach presented here further provides an apparatus which is designed to carry out or execute the steps of a variant of a method presented here in corresponding devices. The object on which the invention is based can also be achieved quickly and efficiently by virtue of these design variants of the invention in the form of an apparatus.

In the present case, an apparatus can be understood to mean an electrical device which processes sensor signals and takes this as a basis for outputting control and/or data signals. The apparatus can have an interface which may be in hardware and/or software form. In the case of a hardware form, the interfaces may be part of what is known as a system ASIC, for example, which contains an extremely wide variety of functions of the apparatus. However, it is also possible for the interfaces to be separate, integrated circuits or at least to some extent to comprise discrete elements. In the case of a software form, the interfaces may be software modules which are present, for example, on a microcontroller together with other software modules.

A computer program product or computer program having program code which can be stored on a machine-readable carrier or storage medium, such as a semiconductor memory, a hard disk memory or an optical memory, and is used to carry out and/or control the steps of the method according to one of the embodiments described above, in particular when the program product is executed on a computer or an apparatus, is also advantageous.

The approach presented here will be explained by way of example in greater detail below with reference to the appended drawings, in which:

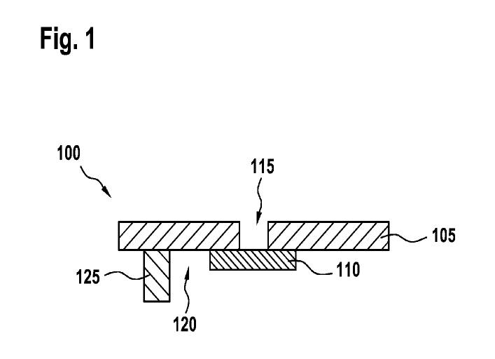

FIG. 1 is a schematic illustration of an electronic module according to an exemplary embodiment of the present invention;

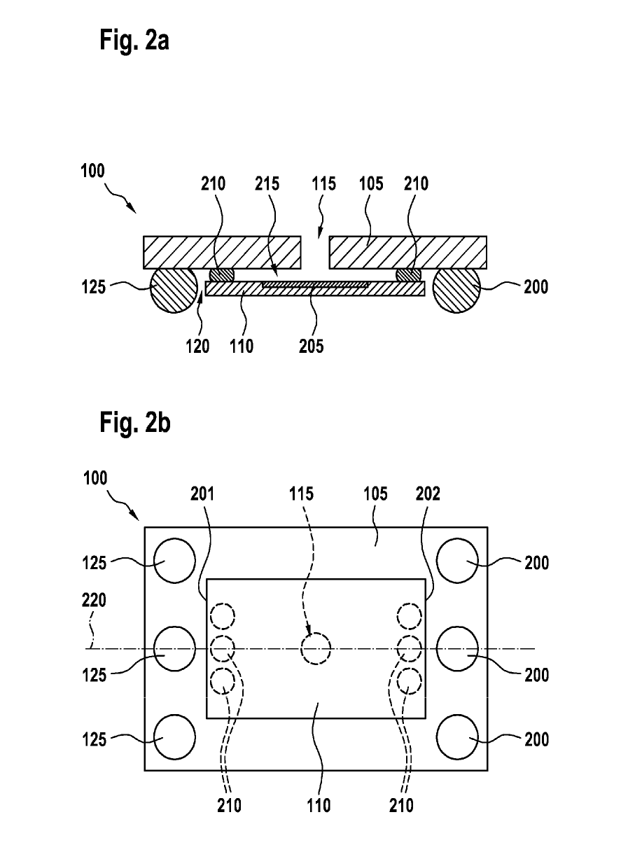

FIGS. 2a, 2b are schematic illustrations of an electronic module according to an exemplary embodiment of the present invention;

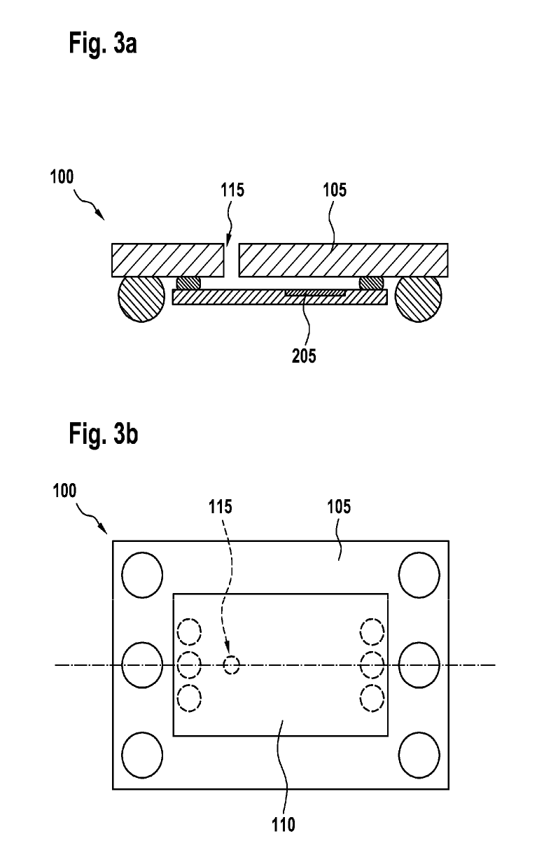

FIGS. 3a, 3b are schematic illustrations of an electronic module according to an exemplary embodiment of the present invention;

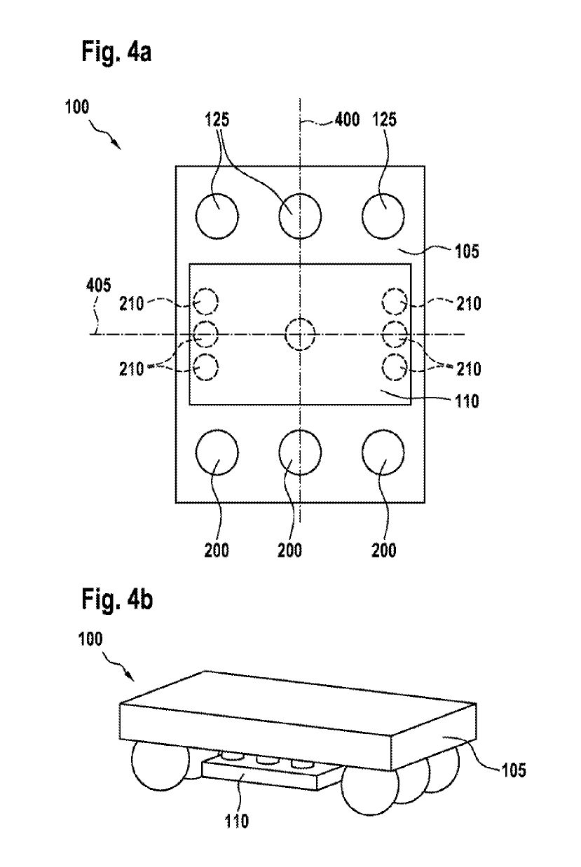

FIGS. 4a, 4b are schematic illustrations of an electronic module according to an exemplary embodiment of the present invention;

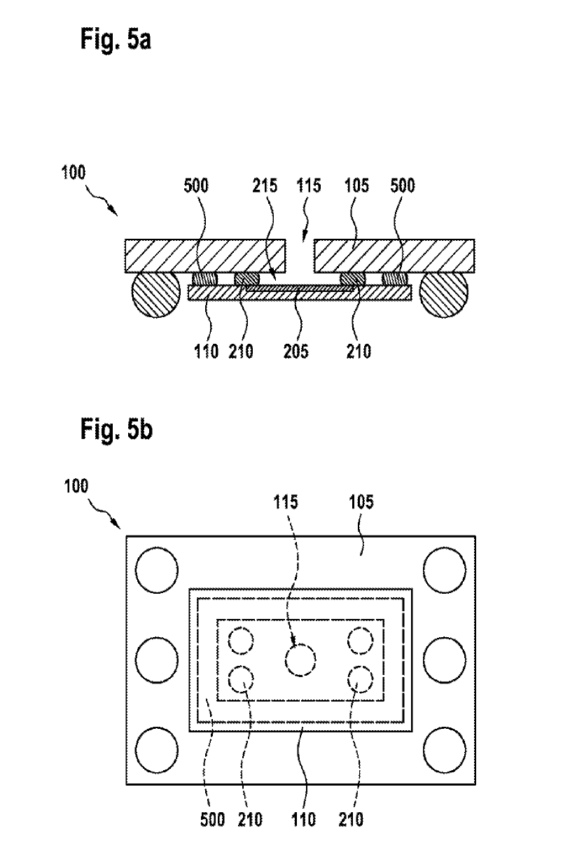

FIGS. 5a, 5b are schematic illustrations of an electronic module according to an exemplary embodiment of the present invention;

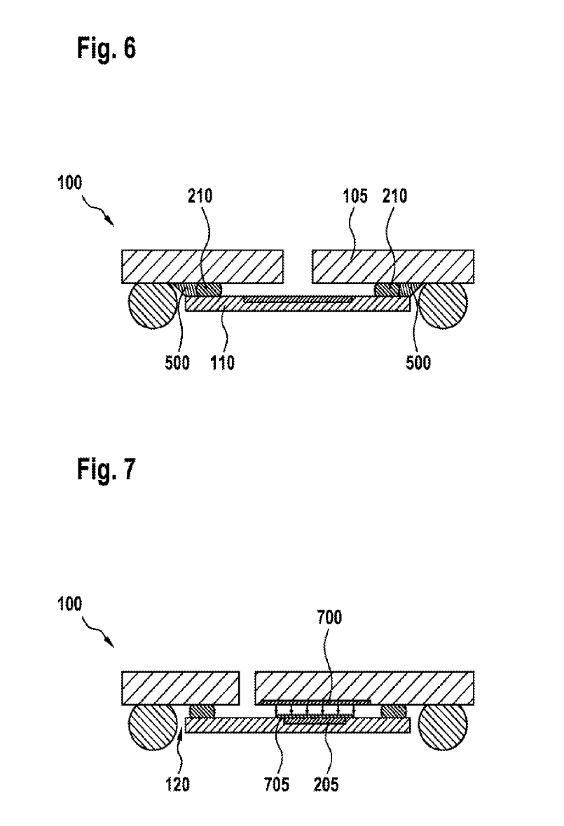

FIG. 6 is a schematic illustration of an electronic module according to an exemplary embodiment of the present invention;

FIG. 7 is a schematic illustration of an electronic module according to an exemplary embodiment of the present invention;

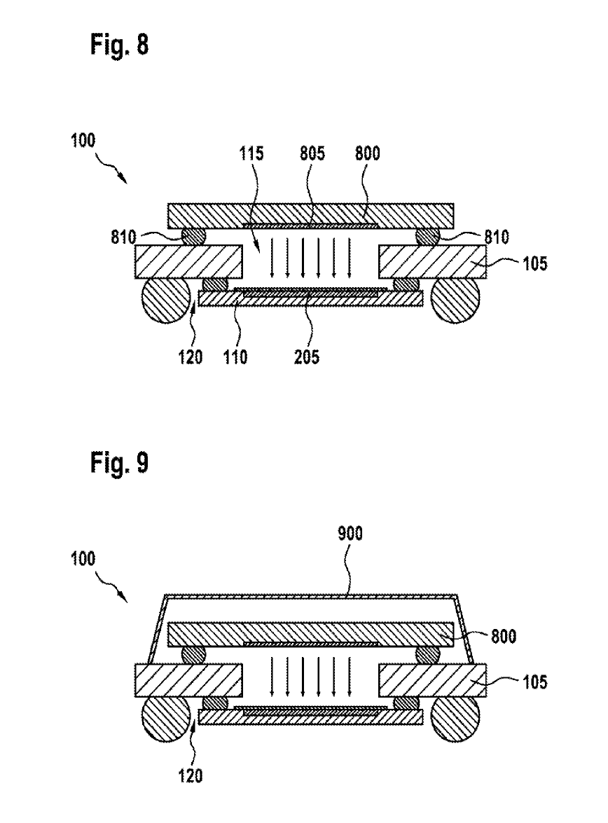

FIG. 8 is a schematic illustration of an electronic module according to an exemplary embodiment of the present invention;

FIG. 9 is a schematic illustration of an electronic module according to an exemplary embodiment of the present invention;

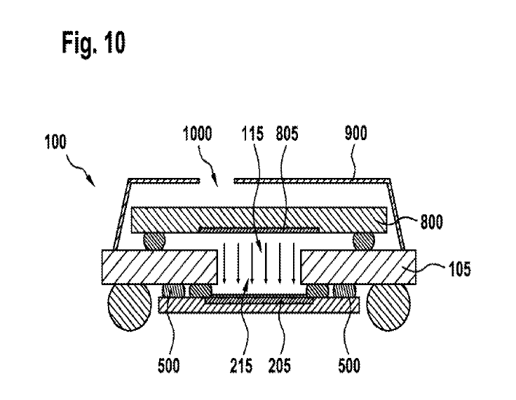

FIG. 10 is a schematic illustration of an electronic module according to an exemplary embodiment of the present invention;

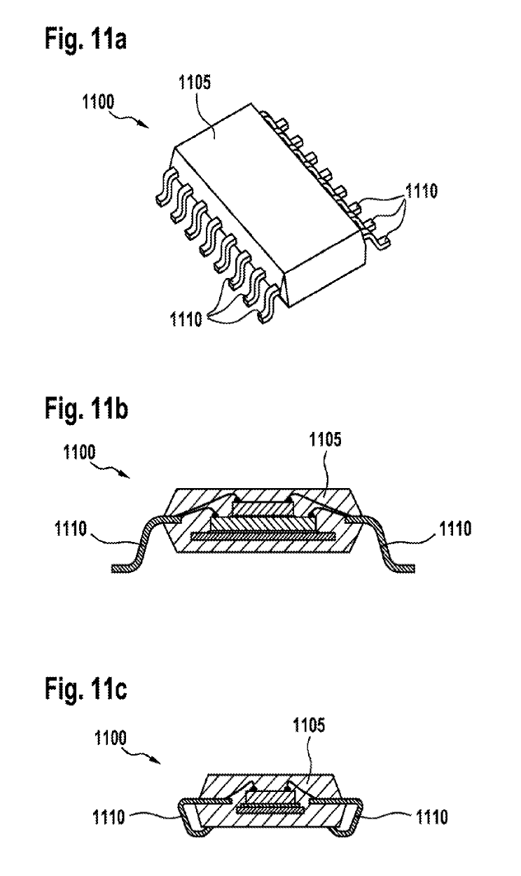

FIGS. 11a, 11b, 11c are schematic illustrations of a conventional electronic module;

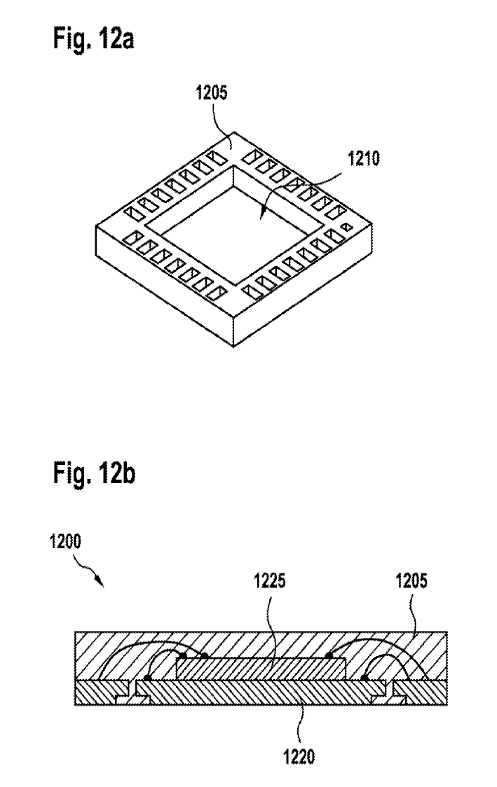

FIGS. 12a, 12b are schematic illustrations of a conventional electronic module;

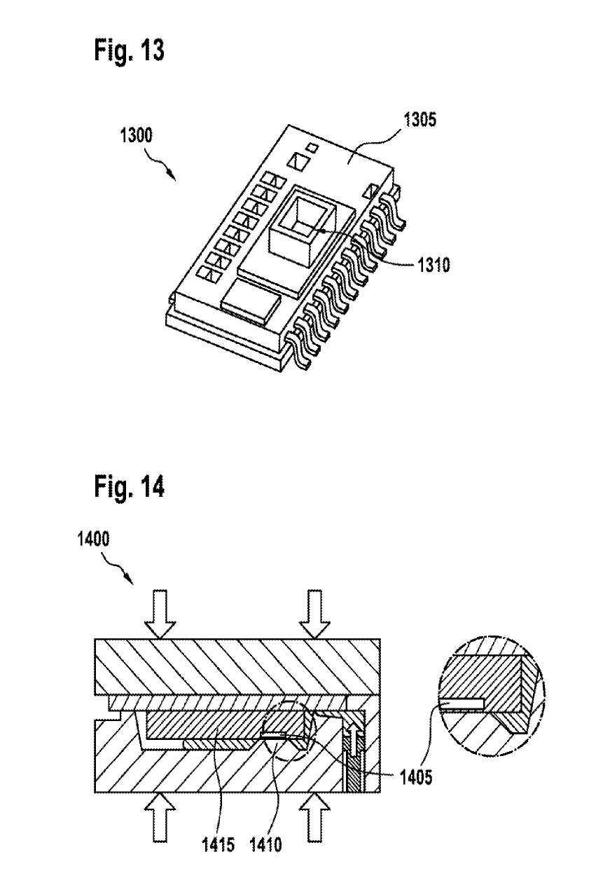

FIG. 13 is a schematic illustration of a conventional electronic module;

FIG. 14 is a schematic illustration of an injection-molding apparatus for producing a conventional electronic module;

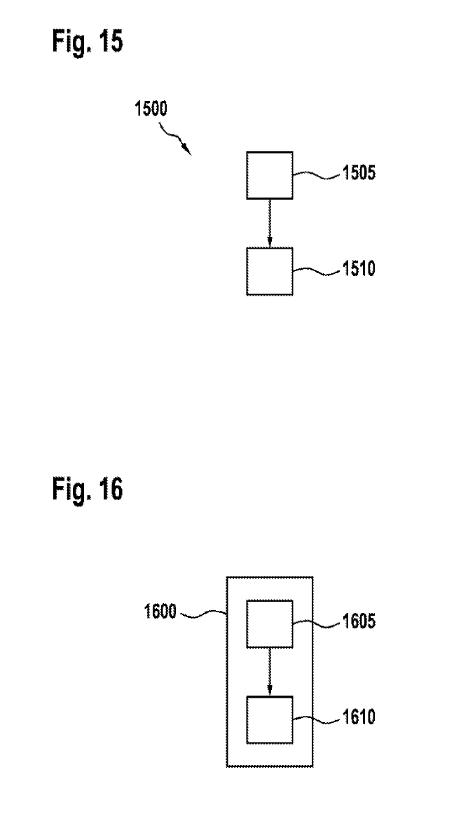

FIG. 15 is a flowchart of a method for producing an electronic module according to an exemplary embodiment of the present invention; and

FIG. 16 is a block diagram of an apparatus for carrying out a method according to an exemplary embodiment of the present invention.

In the following description of expedient exemplary embodiments of the present invention, identical or similar reference symbols are used for the similarly acting elements illustrated in the various figures, with repeated description of these elements being dispensed with.

FIG. 1 is a schematic illustration of an electronic module 1 according to an exemplary embodiment of the present invention. The electronic module 100 comprises a support plate 105 and an electronic component 110. The support plate 105 is designed with a passage opening 115. The electronic component 110 is arranged on a contact-making side 120 of the support plate 105, opposite the passage opening 115. In this case, the electronic component 110 can be electrically conductively connected to the support plate 105. Furthermore, a contact element 125 is arranged on the contact-making side 120. The contact element 125 projects beyond the electronic component 110.

The passage opening 115 is designed to establish a fluidic connection between a surface of the electronic component 110, which surface faces the passage opening 115, and a side of the support plate 105 which is situated opposite the contact-making side 120.

The contact element 125 serves to mechanically fasten the electronic module 100. In addition, the contact element 125 can be designed to make electrical contact with the support plate 105.

FIGS. 2a and 2b are schematic illustrations of an electronic module 100 according to an exemplary embodiment of the present invention. FIG. 2a shows a side view of the electronic module 100; FIG. 2b shows a plan view of the electronic module 100. In contrast to FIG. 1, the electronic module 100 shown in FIGS. 2a and 2b is realized, by way of example, with three contact elements 125 and also three further contact elements 200. The contact elements 125 and the further contact elements 200 are in each case arranged in rows of three here. The three further contact elements 200 are arranged, like the contact elements 125, on the contact-making side 120 and project beyond the electronic component 110.

As shown in FIG. 2b, the contact elements 125 are arranged adjacent to a first edge 201 of the electronic component 110, and the further contact elements 200 are arranged adjacent to a second edge 202 of the electronic component 110, which second edge is situated opposite the first edge 201. The contact elements 125, 200 are realized, for example, as solder balls.

A surface of the electronic component 110, which surface faces the contact-making side 120, comprises a sensitive region 205 which is designed to detect certain physical properties of an external environment of the electronic module 100. The sensitive region 205 is arranged opposite the passage opening 115.

By way of example, six connecting elements 210 in two rows of three are arranged between the electronic component 110 and the support plate 105. By way of example, a first row of three connecting elements 210 extends parallel to a row of three contact elements 125, and a second row of three connecting elements 210 extends parallel to a row of three further contact elements 200. The connecting elements 210 are designed to fasten the electronic component 110 to the support plate 105 and to electrically conductively connect said electronic component to the support plate 105. By virtue of the connecting elements 210, the electronic component 110 is arranged at a distance from the support plate 105 which corresponds substantially to a height of the connecting elements 210. This results in an intermediate space 215 between the electronic component 110 and the support plate 105, said intermediate space being fluidically connected via the passage opening 115 to that side of the support plate 105 which is situated opposite the contact-making side 120.

The connecting elements 210 can, like the contact elements 125, 200, be realized as solder balls.

As shown in FIG. 2b, the support plate 105 and the electronic component 110 are each of rectangular design. By way of example, the support plate 105 and the electronic component 110 extend along a common longitudinal axis 220. In this case, the respective rows of three contact elements 125, further contact elements 200 and connecting elements 210 are arranged transverse to the longitudinal axis 220.

According to an exemplary embodiment of the present invention, a sensor system 100 is provided with a printed circuit board support substrate 105 which has a media access 115. A sensor chip 110 is fastened to a bottom face of the support substrate 105 by means of six solder balls as connecting elements 210. The support substrate 105 has solder balls as contact elements 125, 200 for making contact with a further printed circuit. The solder balls 125, 200 project beyond the sensor chip 110 in the vertical direction. The media access 115 is oriented laterally over a sensitive region 205 of the sensor chip 110. In addition, a lateral media access is produced between support substrate 105 and sensor chip 110 as a result. The lateral media access may be, for example, a region between the solder balls 210.

The printed circuit board 105 can comprise metal conductor tracks for rewiring, metal vias and pad areas. The media access 115 in the support substrate 105 can be produced, for example, by drilling, milling or by laser. Here, the media access 115 can be designed with a round cross section.

FIGS. 3a and 3b are schematic illustrations of an electronic module 100 according to an exemplary embodiment of the present invention. In contrast to FIG. 2a, the passage opening 115 in FIG. 3a is arranged offset in relation to the sensitive region 205, so that the sensitive region 205 is completely covered by the support plate 105. Furthermore, the passage opening 115 is designed, by way of example, with a considerably smaller diameter than in FIGS. 2a and 2b.

A sensor system 100 comprising a media access 115 which is laterally offset in relation to the sensitive structure 205 of the sensor chip 110 has the advantage, for example, of improved particle and light protection. FIGS. 4a and 4b are schematic illustrations of an electronic module 100 according to an exemplary embodiment of the present invention. FIG. 4a illustrates a plan view of the electronic module 100; FIG. 4b is a schematic three-dimensional illustration of the electronic module 100. In contrast to FIGS. 2a and 2b, the support plate 105 and the electronic component 110 in FIGS. 4a and 4b extend along different longitudinal axes. By way of example, a longitudinal axis 400 of the support plate 105 is arranged substantially perpendicular to a longitudinal axis 405 of the electronic component 110. Therefore, the respective rows of three contact elements 125 and further contact elements 200 are also arranged substantially perpendicular to the respective rows of three connecting elements 210.

According to an exemplary embodiment of the present invention, a support substrate 105 and at least one semiconductor chip 110 of a sensor system 100 form two rectangles which are rotated through 90°, that is to say a short edge of the semiconductor chip 110 runs parallel to a long edge of the support substrate 105. In this case, the contact elements 210 of the at least one semiconductor chip 110 and the contact elements 125, 200 of the support substrate 105, in each case as at least two rows, are oriented in the direction of the respective two short edges of a rectangle.

FIGS. 5a and 5b are schematic illustrations of an electronic module 100 according to an exemplary embodiment of the present invention. In contrast to the electronic module 100 shown in FIGS. 2a and 2b, the electronic module 100 in FIGS. 5a and 5b has a sealing edge 500. The sealing edge 500 is arranged between the electronic component 110 and the support plate 105 along an outer edge region of the electronic component 110. The sealing edge 500 is designed to delimit an edge region of the intermediate space 215 and to close said edge region in a fluid-tight manner. In this case, the connecting elements 210 are arranged within the intermediate space 215 which is delimited by the sealing edge 500.

FIGS. 5a and 5b show, by way of example, only four connecting elements 210 instead of six. The connecting elements 210 are arranged in two rows of two in this case.

According to an exemplary embodiment of the present invention, the at least one electronic semiconductor component 110 is fastened to the support substrate 105 by way of a sealing edge 500 in the form of a fastening ring, wherein the fastening ring 500 laterally delimits and seals off the intermediate space 215 between semiconductor component 110 and support substrate 105. The fastening ring 500 may be, for example, a sealing ring which is composed of solder or copper or may be an adhesive, for example an underfiller or sidefiller, as shown in FIG. 6.

FIG. 6 is a schematic illustration of an electronic module 100 according to an exemplary embodiment of the present invention. In contrast to FIGS. 5a and 5b, the sealing edge 500 is realized by an adhesive compound, which is inserted between the support plate 105 and the electronic component 110, in FIG. 6.

FIG. 7 is a schematic illustration of an electronic module 100 according to an exemplary embodiment of the present invention. In contrast to FIGS. 3a and 3b, the contact-making side 120 shown in FIG. 7 comprises an active structure 700, wherein a main portion of the active structure 700 is arranged opposite the sensitive region 205. The active structure 700 is designed, for example, in order to heat the sensitive region 205.

According to an exemplary embodiment of the present invention, a further sensitive and/or active structure 700, for example an integrated radiation source in the form of an infrared source or heating structure, is formed in a region of the support substrate 105 which is close to the surface, in a manner oriented toward the sensitive and/or active structure 205 of the at least one semiconductor component 110. Furthermore, the chip 110 can comprise a detector 705, for example an infrared detector, in addition to the sensitive material 205.

FIG. 8 is a schematic illustration of an electronic module 100 according to an exemplary embodiment of the present invention. In contrast to FIGS. 2a and 2b, the passage opening 115 shown in FIG. 8 is designed with a diameter which corresponds substantially to a width of the sensitive region 205. In addition, the electronic module 100 comprises a further electronic component 800 which is fastened on a side of the support plate 105 which is situated opposite the contact-making side 120. By way of example, the further electronic component 800 is soldered onto the support plate 105 by means of solder balls.

The further electronic component 800 comprises an active region 805 which is arranged opposite the passage opening 115 and therefore the sensitive region 205 of the electronic component 110. In this case, the active region 805 is realized, by way of example, with a width which corresponds substantially to the diameter of the passage opening 115.

The active region 805 can be designed in a similar manner to the active structure 700 shown in FIG. 7, in order to irradiate the sensitive region 205.

According to an exemplary embodiment of the present invention, at least one further electronic semiconductor component 800 is attached to a top side of a plastic support substrate 105 by way of at least one further contact element 810. The at least one further electronic component 800 has a sensitive and/or active structure 805 which is close to the surface and is located on a side of the semiconductor component 800 which is oriented toward the plastic support substrate 105.

In this case, a fluidic through-hole 115 in the support substrate 105 is designed in terms of its lateral dimensions in such a way that the sensitive and/or active structures 205, 805 of the two semiconductor components 110, 800 are situated opposite one another in an uncovered manner.

By way of example, a chip 800 is realized as a UV diode or infrared source in order to function as radiation source.

FIG. 9 is a schematic illustration of an electronic module 100 according to an exemplary embodiment of the present invention. In contrast to the electronic module 100 shown in FIG. 8, the electronic module 100 shown in FIG. 9 comprises a cover element 900 which is fastened on that side of the support plate 105 which is situated opposite the contact-making side 120 and spans the further electronic component 800 in order to protect the further electronic component 805 against environmental influences. The cover element 900 can also be called cover or covering.

FIG. 10 is a schematic illustration of an electronic module 100 according to an exemplary embodiment of the present invention. In contrast to FIG. 9, the cover element 900 shown in FIG. 10 has a cover opening 1000 as media access. Furthermore, the module 100 shown in FIG. 10 has the sealing edge 500 which is described with reference to FIGS. 5a and 5b. The sensitive region 205 and the active region 805 are additionally designed to be slightly wider than the passage opening 115.

FIGS. 11a to 11c are schematic illustrations of a conventional electronic module 1100. FIG. 11a is a schematic three-dimensional illustration of the module 1100. The module 1100 is realized by a solid-cast housing 1105. The solid-cast housing 1105 can also be called an SOIC full-mold housing (SOIC=small outline integrated circuit). Two sides of the solid-cast housing 1105 which are situated opposite one another each have a plurality of contact wires 1110, also called leads, which are bent in an s-shape and serve to make electrical contact with the module 1100.

As shown in FIG. 11b, the module 1100 which is encapsulated by the solid-cast housing 1105 comprises a stack of plates comprising a first silicon chip 1115, a second silicon chip 1120 and a substrate 1125, also called die pad. The silicon chips 1115, 1120 are electrically conductively connected to the contact wires 1110 by means of gold wires.

In FIG. 11c, the contact wires 1110 are bent in a j-shape, also called j-formed leadframe. The contact wires 1110 are produced, for example, from copper.

FIGS. 12a and 12b are schematic illustrations of a conventional electronic module 1200. The module 1200 comprises a contactless injection-molded housing 1205 which is shown separately in FIG. 12a. The injection-molded housing 1205 can also be called a leadless molded housing. The injection-molded housing 1205 has a rectangular central opening 1210. A plurality of rectangular contact-making openings 1215 are arranged around the opening 1210.

As shown in FIG. 12b, the electronic module 1200 comprises a copper sheet 1220 on which a silicon chip 1225 is fastened. The copper sheet 1220 can also be called a leadframe. The silicon chip 1225 is electrically conductively connected to the copper sheet 1220 by means of gold wires. The silicon chip 1225 is encapsulated by the injection-molded housing 1205.

Micromechanical sensors are usually packaged in molded housings. In this case, a distinction can be made between so-called leaded housings, which have bent contact feet for a second-level contact-making connection and can be completely remolded, and over-molded so-called leadless housings without contact legs. The second-level contact-making connection can be realized by means of contact areas on a package bottom side in this case.

FIG. 13 is a schematic illustration of a conventional electronic module 1300. The module 1300 is integrated into a so-called premold housing 1305. Said premold housing is a prefabricated, injection-molded main housing which can be closed by a cover after a silicon chip is positioned and contact is made with said silicon chip. The premold housing 1305 constitutes a low-stress package form since there is no direct contact between the bond partners silicon and encapsulation compound.

A cavity within the package 1300 can be connected to an external environment by means of a package opening 1310, which functions as media access, for example in the cover. The media access can be used, for example, for pressure sensors, infrared sensors, gas sensors and microphones. Media accesses of this kind can also be realized in housings with transfer-molded encapsulation of components, also called full-mold packages, as described above with reference to figures lla to 11c.

FIG. 14 is a schematic illustration of an injection-molded apparatus 1400 for producing a conventional electronic module 1405. A method for realizing this package form is based on the so-called film-assisted molding method (FAM). In this case, a media access 1405 is realized by means of the shape of a mold. Here, a projecting mold structure 1410 is placed directly on a silicon chip 1415 and prevents, for example, overmolding of a pressure sensor diaphragm. The mold can be coated with an ETFE film (ETFE=ethylene tetrafluoroethylene) for the purpose of tolerance compensation. Said film is highly deformable and lies over a mold surface so as to match its shape.

In this method, there is a direct relationship between the sensor layout and mold structures. The mold should cover the active diaphragm structures without concealing pad areas or wire bonds. Therefore, certain design rules have to be complied with.

Furthermore, depending on the layout, it may be necessary to also completely replace the mold 1410 on active structures such as diaphragms, this possibly leading to severe mechanical loading. In addition, it is difficult to realize undercuts in the case of cavities using this method.

FIG. 15 shows a flowchart of a method 1500 for producing an electronic module according to an exemplary embodiment of the present invention. The method 1500 comprises a step 1505 of providing at least one support plate having at least one passage opening, wherein a contact-making side of the support plate has at least one contact element, and also at least one electronic component. Furthermore, the method 1500 comprises a step 1510 of forming a composite comprising the support plate and the electronic component. Here, the electronic component is arranged on the contact-making side, opposite the passage opening, wherein the contact element projects beyond the electronic component.

FIG. 16 shows a block diagram of an apparatus 1600 for carrying out a method according to an exemplary embodiment of the present invention. The apparatus 1600 comprises a unit 1605 which is designed in order to provide at least one support plate having at least one passage opening and also at least one electronic component, wherein a contact-making side of the support plate has at least one contact element. Furthermore, the apparatus 1600 comprises a unit 1610 which is designed in order to form a composite comprising the support plate and the electronic component. Here, the electronic component is arranged on the contact-making side, opposite the passage opening, wherein the contact element projects beyond the electronic component.

According to an exemplary embodiment which is shown in the figures described above, a sensor 100 or a sensor housing 100 and a method for producing the sensor 100 comprise a plastic support substrate 105, at least one electronic semiconductor component 110, at least one first metal contact element 210 and also at least one second metal contact element 125.

Here, the at least one electronic semiconductor component 110 is attached to a bottom side of the plastic support substrate 105 by way of the at least one first metal contact element 210 and also the at least one second metal contact element 125, wherein the at least one second metal contact element 125 projects vertically beyond the at least one electronic semiconductor component 110.

The plastic support substrate 105 is, for example, a thermoset printed circuit board (PCB) comprising a glass fiber-reinforced portion, metal conductor tracks, metal pad areas and metal vias. The support substrate 105 is therefore realized as a thermoset circuit or rewiring support.

The electronic semiconductor component 110 can have a sensitive and/or active structure 205 which is close to the surface and is located on a top side of the semiconductor component 110 which is oriented toward the thermoset support substrate 105.

The thermoset support substrate 105 can have a fluidic through-hole 115 which is arranged directly above the sensitive/active structure 205 as viewed laterally.

The fluidic through-hole 115 can also be arranged in a manner laterally offset with respect to the sensitive and/or active structure 205.

Furthermore, the fluidic through-hole 115 can be designed to be considerably smaller than the sensitive and/or active structure 205 in respect of its lateral dimensions.

The contact elements 125, 210 can be designed as solder balls, solder bumps, copper pillars or gold studs.

Diaphragms, heating structures, radiation-emitting structures, polymeric layers, diode structures, transistor structures, metal layers, interdigital structures or appropriate combinations, for example, can be used as sensitive structures 205, 700, 805 which are close to the surface.

The exemplary embodiments described and shown in the figures are selected only by way of example. Different exemplary embodiments can be combined with one another in full or in respect of individual features. It is also possible for one exemplary embodiment to have features of a further exemplary embodiment added to it.

Furthermore, the method steps presented here can be repeated and also executed in an order different to that described.

If an exemplary embodiment comprises an “and/or” conjunction between a first feature and a second feature, this is intended to be read to mean that the exemplary embodiment has both the first feature and also the second feature according to one embodiment, and either only the first feature or only the second feature according to a further embodiment.

1. An electronic module comprising:
at least one support plate having a contact-making side that includes at least one contact element; and
at least one electronic component positioned on the contact-making side of the at least one support plate,
wherein the at least one contact element projects beyond the at least one electronic component.

2. The electronic module as claimed in claim 1, wherein:
the at least one support plate further has a further side that is opposite the contact-making side; and
the support plate defines at least one passage opening, that is located opposite the electronic component and that forms a fluidic channel between the contact-making side and the further side of the at least one support plate.

3. The electronic module as claimed in claim 2, further comprising:
at least one connecting element that electrically conductively connects the at least one electronic component to the at least one support plate wherein at least one of:
the at least one connecting element is positioned between the at least one electronic component and the at least one support plate so as to define, at least in a region of the at least one passage opening, an intermediate space between the at least one electronic component and the at least one support plate; and
the at least one support plate includes a plastic, at least in part.

4. The electronic module as claimed in claim 2, further comprising a sealing edge is formed at least partially around the passage opening between the at least one electronic component and the at least one support plate to connect the at least one electronic component to the at least one support plate in an at least partially fluid-tight manner.

5. The electronic module as claimed in claim 2, wherein the at least one electronic component has a sensitive region that is configured to detect at least one physical property of an external environment of the electronic module and that is located opposite at least one of the contact-making side and the passage opening.

6. The electronic module as claimed in claim 5, wherein the contact-making side has an active structure that is configured to influence at least one physical property of an external environment of the sensitive region, and that is that is positioned opposite the sensitive region.

7. The electronic module as claimed in claim 2, wherein the at least one support plate further has a further side that is opposite the contact-making side, the electronic module further comprising:
at least one further electronic component that is positioned on the further side of the at least one support plate and opposite the passage opening, and that is electrically conductively connected to the at least one support plate.

8. The electronic module as claimed in claim 7, wherein the at least one further electronic component has a further active region that is configured to influence at least one physical property of an external environment of the at least one further electronic component and that is located opposite the passage opening.

9. The electronic module as claimed in claim 7, further comprising:
a cover element that is fastened to the further side of the support plate and that at least partially projects beyond the at least one further electronic component to protect the at least one further electronic component against environmental influences.

10. The electronic module as claimed in claim 1, wherein:
the contact-making side further has at least one further contact element; and
at least one of:
the at least one further contact element projects beyond the at least one electronic component;
the at least one further contact element is positioned adjacent to a first edge of the at least one electronic component; and
the contact element is arranged adjacent to a second edge of the at least one electronic component located opposite the first edge.

11. The electronic module as claimed in claim 1, wherein the at least one support plate and the at least one electronic component are oriented such that an axis of main extent of the at least one support plate and an axis of main extent of the at least one electronic component point in different directions.

12. A method for producing an electronic module, comprising:
providing at least one support plate having a contact-making side that includes at least one contact element;
arranging at least one electronic component on the contact-making side of the at least one support plate so that the at least one contact element projects beyond the at least one electronic component; and
forming a composite from the at least one support plate and the at least one electronic component.

13. An apparatus configured to at least one of perform and control performance of each of a set of acts including:
providing at least one support plate having a contact-making side that includes at least one contact element;
arranging at least one electronic component on the contact-making side of the at least one support plate so that the at least one contact element projects beyond the at least one electronic component; and
forming a composite from the at least one support plate and the at least one electronic component.

14. The apparatus as claimed in claim 13, comprising:
a processor; and
computer readable instructions that, when executed by the processor, cause the apparatus to at least one of perform and control performance of the set of acts.

15. The apparatus as claimed in claim 14, further comprising:
a computer readable data storage memory, the computer readable instructions stored on the computer readable data storage memory.
